(19) United States
(12) Patent Application Publication
(10) Pub. No.: US 2026/0344330 A1
(43) Pub. Date: Oct. 29, 2026

(54) SUBSTRATE PROCESSING METHOD AND SUBSTRATE PROCESSING APPARATUS

(71) Applicant: Tokyo Electron Limited, Tokyo (JP)

(72) Inventor: Kyotaro KANEHISA, Koshi City (JP)

(21) Appl. No.: 19/400,033

(22) Filed: Nov. 25, 2025

(30) Foreign Application Priority Data
Nov. 29, 2024 (JP) 2024-208746

(51) Int. Cl. H10P 72/00

(52) U.S. Cl. CPC H10P 72/0414; H10P 72/0604

(57) ABSTRACT

A substrate processing method includes holding an outer peripheral edge of a substrate by a conductive holder and supplying a chemical liquid onto an upper surface of the substrate via a supply tube having a conductive member provided on an outer surface of the supply tube, wherein the conductive member is electrically connected to one end of a variable resistor, wherein the holder is electrically connected to the other end of the variable resistor, and wherein the supplying the chemical liquid includes a first sub-process of setting the resistance value of the variable resistor to a first value; a second sub-process of supplying the chemical liquid onto the upper surface of the substrate via the supply tube; and a third sub-process of changing the resistance value of the variable resistor to a second value lower than the first value while continuously supplying the chemical liquid.

### CROSS-REFERENCE TO RELATED APPLICATION

This application is based upon and claims the benefit of priority from Japanese Patent Application No. 2024-208746, filed on Nov. 29, 2024, the entire content of which is incorporated herein by reference.

### TECHNICAL FIELD

The present disclosure relates to a substrate processing method and a substrate processing apparatus.

### BACKGROUND

Patent Document 1 discloses a substrate processing method including: supplying an antistatic liquid having a first specific resistance, which is greater than a specific resistance of a processing liquid, onto a main surface of a substrate, and paddling the entire main surface with the antistatic liquid; reducing the specific resistance of the antistatic liquid supplied onto the main surface of the substrate to a second specific resistance, which is smaller than the first specific resistance, and paddling the entire main surface of the substrate with the antistatic liquid having the second specific resistance to reduce electric charges on the main surface of the substrate; and supplying the processing liquid onto the main surface of the substrate to perform a predetermined processing.

### PRIOR ART DOCUMENT

### Patent Document

Patent Document 1: Japanese Patent Laid-open Publication No. 2015-119128

### SUMMARY

A substrate processing method according to the present disclosure includes: a holding process of holding an outer peripheral edge of a substrate by a conductive holder, and after the holding process, a chemical liquid supply process of supplying a chemical liquid onto an upper surface of the substrate via a first supply tube having a first conductive member provided on an outer peripheral surface of the first supply tube, wherein the first conductive member is electrically connected to one end of a first variable resistor having a variable resistance value, wherein the holder is electrically connected to the other end of the first variable resistor, and wherein the chemical liquid supply process includes: a first sub-process of setting the resistance value of the first variable resistor to a first value; after the first sub-process, a second sub-process of supplying the chemical liquid onto the upper surface of the substrate via the first supply tube; and after the second sub-process, a third sub-process of changing the resistance value of the first variable resistor to a second value lower than the first value while continuously supplying the chemical liquid from the second sub-process onto the upper surface of the substrate via the first supply tube.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a plan view schematically illustrating an example of a substrate processing system.

FIG. 2 is a diagram schematically illustrating an example of a liquid processing unit, and is a cross-sectional view illustrating a state in which a substrate is located at a lowered position.

FIG. 3 is a perspective view illustrating a vicinity of a rotary plate and a support plate in the liquid processing unit of FIG. 2.

FIG. 4 is a diagram schematically illustrating an example of the liquid processing unit, and is a cross-sectional view illustrating a state in which the substrate is located at a raised position.

FIG. 5 is a diagram schematically illustrating a state in which a processing liquid is supplied from a supply tube to a substrate held by a holder.

FIG. 6A is a cross-sectional view taken along line VIA-VIA of FIG. 5, illustrating an example of the supply tube, and FIG. 6B is a cross-sectional view illustrating another example of the supply tube.

FIG. 7 is a block diagram illustrating an example of main components of the substrate processing system.

FIG. 8 is a schematic diagram illustrating an example of a hardware configuration of a controller.

FIG. 9 is a longitudinal cross-sectional view illustrating an example (first example) of a variable resistor.

FIG. 10A is a longitudinal cross-sectional view illustrating another example (second example) of the variable resistor, and illustrates a state in which electrical conduction between the supply tube and a ground is established in the variable resistor. FIG. 10B is a cross-sectional view taken along line B-B of FIG. 10A.

FIG. 11A is a longitudinal cross-sectional view illustrating the same example (second example) of the variable resistor, and illustrates a state in which electrical insulation between the supply tube and a ground is established in the variable resistor. FIG. 11B is a cross-sectional view taken along line B-B of FIG. 11A.

FIG. 12A is a longitudinal cross-sectional view illustrating another example (third example) of the variable resistor, and illustrates a state in which electrical conduction between the supply tube and a ground is established in the variable resistor. FIG. 12B is a longitudinal cross-sectional view illustrating the same example (third example) of the variable resistor, and illustrates a state in which electrical insulation between the supply tube and a ground is established in the variable resistor.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

In the following description, the same reference numerals are used for the same elements or elements having the same functions, and redundant descriptions thereof are omitted. In addition, in this specification, the terms “up,” “down,” “right,” and “left” in the drawings are on the basis of the orientation of the reference numerals in the drawings.

### Substrate Processing System

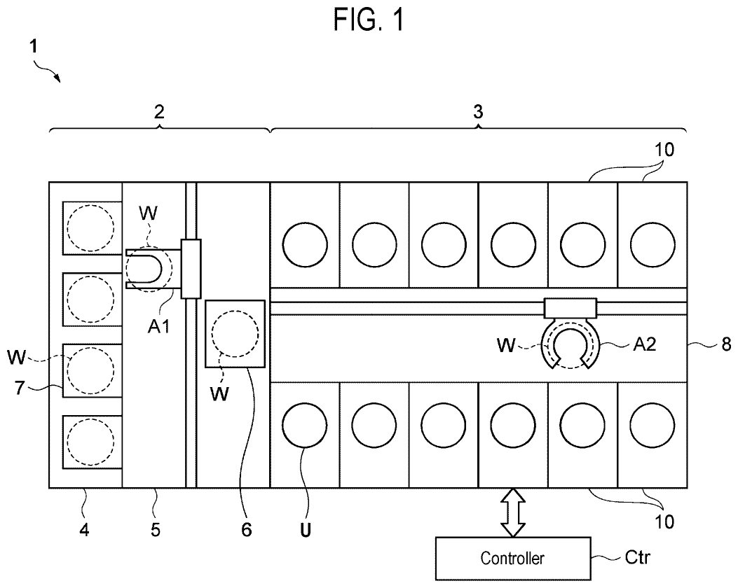

First, a substrate processing system 1 (substrate processing apparatus) configured to process a substrate W will be described with reference to FIG. 1. The substrate processing system 1 includes a load/unload station 2, a processing station 3, and a controller Ctr. The load/unload station 2 and the processing station 3 may be arranged in a single row in a horizontal direction, for example.

The substrate W may have a disk shape, or may have a plate shape other than a disk, such as polygonal. The substrate W may also have a cutout at which a portion of the substrate W is cut out. The cutout may be, for example, a notch (a U-shaped or V-shaped groove), or may be a linear portion (so-called “orientation flat”) extending in a straight line. The substrate W may be, for example, a semiconductor substrate (silicon wafer), a glass substrate, a mask substrate, a flat panel display (FPD) substrate, or various other types of substrates. A diameter of the substrate W may be, for example, approximately 200 mm to 450 mm.

The load/unload station 2 includes a stage 4, a loader/unloader 5, and a shelf unit 6. The stage 4 includes a plurality of stages (not illustrated) arranged in a width direction (up-down direction in FIG. 1). Each stage is configured to place a carrier 7 on the stage. The carrier 7 is configured to accommodate at least one substrate W in a sealed state. The carrier 7 includes an opening/closing door (not illustrated) for loading and unloading the substrate W.

The loader/unloader 5 is disposed adjacent to the stage 4 in a direction in which the load/unload station 2 and the processing station 3 are aligned (left-right direction in FIG. 1). The loader/unloader 5 includes an opening/closing door (not illustrated) provided for the stage 4. When both the opening/closing door of the carrier 7 and the opening/closing door of the loader/unloader 5 are open in a state in which the carrier 7 is placed on the stage 4, an interior of the load/unload portion 5 and an interior of the carrier 7 are brought into communication with each other.

The loader/unloader 5 incorporates a transport arm A1. The transport arm Al is configured to be movable horizontally in a width direction of the load/unload portion 5, movable vertically in a vertical direction, and rotatable about a vertical axis. The transport arm Al is configured to take out the substrate W from the carrier 7 and deliver it to the shelf unit 6, and also to receive the substrate W from the shelf unit 6 and return it into the carrier 7. The shelf unit 6 is located in a vicinity of the processing station 3 and is configured to accommodate the substrate W.

The processing station 3 includes a transporter 8 and a plurality of liquid processing units U. The transporter 8 extends horizontally, for example, in a direction in which the load/unload station 2 and the processing station 3 are aligned (left-right direction in FIG. 1). The transporter 8 incorporates a transport arm A2. The transport arm A2 is configured to be movable horizontally in an extension direction of the transporter 8, movable vertically in the vertical direction, and rotatable about a vertical axis. The transport arm A2 is configured to take out the substrate W from the shelf unit 6 and deliver it to the liquid processing unit U, and also to receive the substrate W from the liquid processing unit U and return it into the shelf unit 6.

The plurality of liquid processing units U are arranged in a single row along the extension direction of the transporter 8 (left-right direction in FIG. 1) on both sides of the transporter 8. A configuration of the liquid processing unit U will be described later.

The controller Ctr, as will be described in detail later, is configured to control the substrate processing system 1 either partially or entirely.

### Liquid Processing Unit

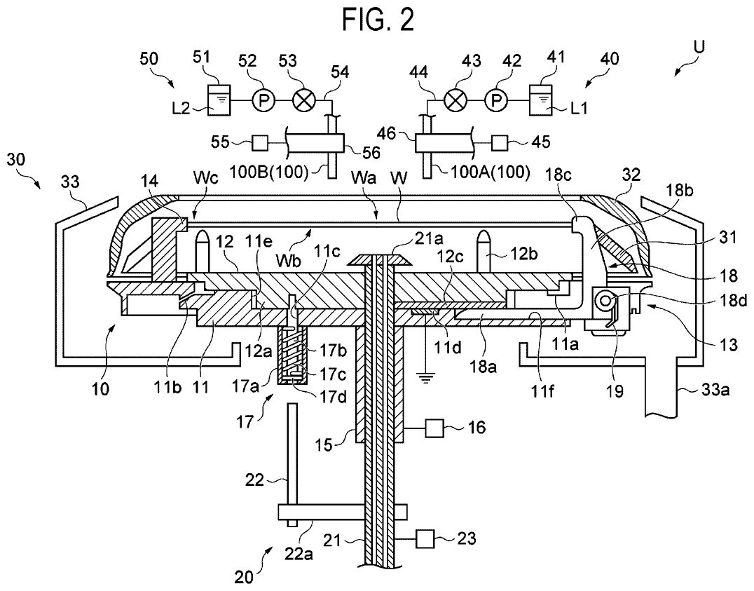

A configuration of the liquid processing unit U will be described with reference to FIGS. 2 to 7. The liquid processing unit U includes a rotary holder 10, an elevator 20, a cup 30, a chemical liquid supplier 40, and a cleaning liquid supplier 50, as illustrated in FIG. 2.

The rotary holder 10 includes a rotary plate 11, a support plate 12, a holder 13, and a restrictor 14.

The rotary plate 11 is, for example, a disk having a larger diameter than the substrate W. The rotary plate 11 includes a collection groove 11a provided in an upper surface of the rotary plate 11 so as to extend in a circumferential direction of the rotary plate 11, a discharge hole 11b extending from a bottom surface of the collection groove 11a toward an outer circumferential surface of the rotary plate 11 in a radial direction of the rotary plate 11, and a plurality of through-holes 11c.

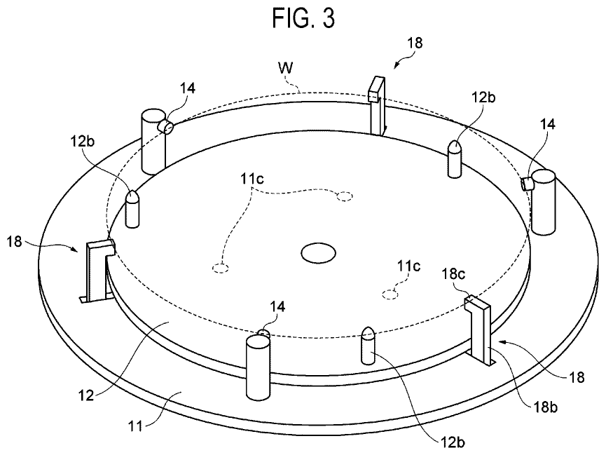

The collection groove 11a is configured to collect a processing liquid (chemical liquid L1 and cleaning liquid L2, which will be described later) that has entered between the rotary plate 11 and the support plate 12. The discharge hole 11b is inclined downward toward a radially outward direction, and is configured to discharge the processing liquid collected in the collection groove 11a to the outside by using a centrifugal force of the rotary plate 11. The plurality of through-holes 11c penetrate the rotary plate 11 along the vertical direction. The plurality of through-holes 11c may be arranged at approximately equal intervals to form a circular shape as a whole when viewed from above. As illustrated in FIG. 3, when the number of through-holes 11c is three, the through-holes 11c may be arranged at approximately 120-degree intervals.

The rotary plate 11 is connected to an upper end of a rotary shaft 15 extending in the vertical direction from a lower surface of a central portion of the rotary plate 11. The rotary shaft 15 is connected to a drive 16. The drive 16 is configured to operate based on an operation signal from the controller Ctr to rotate the rotary shaft 15. As the drive 16 rotates the rotary shaft 15, the rotary plate 11 rotates together with the rotary shaft 15 in an approximately horizontal posture around the rotary shaft 15. The drive 16 may be, for example, a rotary motor.

A conductor 11d made of a conductive material is provided in a portion of the upper surface of the rotary plate 11. The conductor 11d is grounded via a conductive wire.

The support plate 12 is, for example, a disk having approximately the same size as the substrate W. The support plate 12 includes a downwardly protruding convex 12a. The convex 12a is configured to be inserted into a concave 11e formed in the upper surface of the rotary plate 11. When the support plate 12 is placed on the rotary plate 11, the convex 12a of the support plate 12 and the concave 11e of the rotary plate 11 fit each other, and a lower surface of the support plate 12 comes into contact with the upper surface of the rotary plate 11. In this state, the support plate 12 rotates integrally with the rotary plate 11.

The support plate 12 includes a plurality of protrusions 12b that protrude upward from an upper surface of the support plate 12, as illustrated in FIGS. 2 and 3. The plurality of protrusions 12b are configured such that tips of the plurality of protrusions 12b are brought into contact with a lower surface Wb of the substrate W to support the substrate W substantially horizontally at a position floated up from the upper surface of the support plate 12. The plurality of protrusions 12b may be disposed at approximately equal intervals in a vicinity of an outer periphery of the support plate 12 to form a circular shape as a whole when viewed from above.

A conductor 12c made of a conductive material is provided in a portion of the lower surface of the support plate 12. The conductor 12c is positioned to overlap with the conductor 11d of the rotary plate 11 and a pressed portion 18a of a movable member 18 (described later) when viewed in the vertical direction.

A plurality of uplifters 17 are provided on the lower surfaces of the rotary plate 11 and the support plate 12. Each uplifter 17 includes a cylinder 17a, a uplifting pin 17b, and a spring 17c.

The cylinder 17a is attached to the lower surface of the rotary plate 11. The cylinder 17a is in communication with the through-hole 11c of the rotary plate 11 and extends in the vertical direction. The uplifting pin 17b is inserted into the cylinder 17a and can move up and down inside the cylinder 17a. An upper end of the uplifting pin 17b is connected to the convex 12a of the support plate 12. A flange 17d having a size approximately the same as an inner diameter of the cylinder 17a is provided at a lower end of the uplifting pin 17b. The spring 17c is, for example, a compression coil spring. The spring 17c is disposed between the lower surface of the rotary plate 11 and the flange 17d of the uplifting pin 17b so as to surround the uplifting pin 17b.

The holder 13 is configured to hold the substrate W together with the restrictor 14 by pressing an outer peripheral edge Wc of the substrate W against the restrictor 14. The holder 13 includes the movable member 18 and a spring 19.

The movable member 18 is electrically conductive. The movable member 18 may be made of, for example, a conductive resin in which conductive particles such as carbon filler or carbon black are dispersed. The resin may be, for example, perfluoroalkoxy alkane (PFA) or polyether ether ketone (PEEK).

The movable member 18 is substantially L-shaped, and includes the pressed portion 18a and an upright portion 18b. The pressed portion 18a extends in the horizontal direction from an outer peripheral edge of the support plate 12 toward the center, so as to be positioned in a groove 11f formed in the rotary plate 11.

The upright portion 18b extends upward continuously from an outer end of the pressed portion 18a and is disposed outward of the outer peripheral edge of the support plate 12. A tip end portion 18c of the upright portion 18b extends radially inward of the rotary plate 11. A groove (not illustrated) may be formed in an inner peripheral surface of the tip end portion 18c at a position corresponding to the outer peripheral edge Wc of the substrate W. By inserting and fitting the outer peripheral edge Wc of the substrate W into the groove, the outer peripheral edge Wc of the substrate W can be held while being pressed against the restrictor 14.

The movable member 18 is rotatably supported around a rotary shaft 18d in a vicinity of the lower end of the upright portion 18b. The rotary shaft 18d extends in a direction tangential to the outer peripheral edge of the support plate 12 when viewed from above.

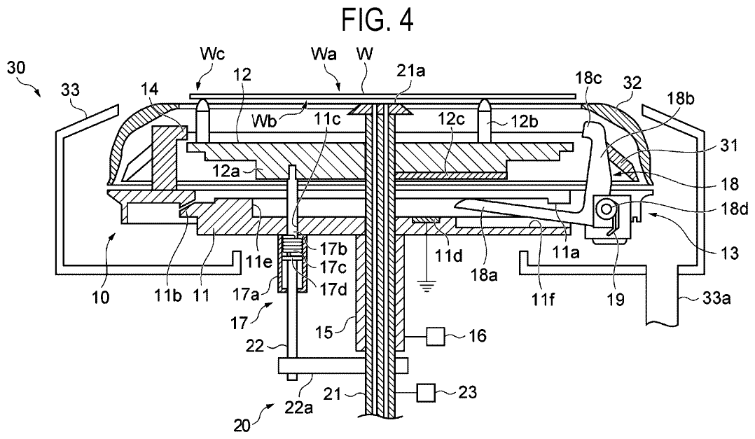

The spring 19 is, for example, a torsion spring wound around the rotary shaft 18d. One end of the spring 19 is connected to a side surface of the movable member 18. The spring 19 presses the upright portion 18b in a direction in which the upright portion 18b collapses radially outward of the rotary plate 11. Therefore, when the support plate 12 moves to a raised position (described in detail later), an inner end portion of the pressed portion 18a jumps up and protrudes from the groove 11f, and an upper end portion of the upright portion 18b moves radially outward of the rotary plate 11, as illustrated in FIG. 4.

The restrictor 14 is fixed at a predetermined position (e.g., a position facing the movable member 18 with the substrate W interposed therebetween). The restrictor 14 is configured to restrict the outer peripheral edge Wc of the substrate W and hold the substrate W in cooperation with the movable member 18 when the support plate 12 is placed on the rotary plate 11, that is, when the support plate 12 is moved to a lowered position (described in detail later).

As illustrated in FIG. 3, a plurality of restrictors 14 are provided at predetermined positions along the circumferential direction of the support plate 12. One restrictor 14, or two or more restrictors 14 may be provided at positions facing the movable member 18.

The elevator 20 includes a supply pipe 21, a plurality of shafts 22, and a drive 23, as illustrated in FIG. 2.

The supply pipe 21 is a hollow tubular member extending in the vertical direction. A plurality of flow paths may be provided in the supply pipe 21. The supply pipe 21 is inserted into and penetrates the rotary shaft 15. A tip end portion of the supply pipe 21 penetrates the rotary plate 11 and the support plate 12 and is positioned above the upper surface of the support plate 12. A nozzle 21a is provided at the tip end portion of the supply pipe 21.

At least one flow path extending along an extension direction of the supply pipe 21 is formed inside the supply pipe 21. The at least one flow path is connected to a liquid source and/or gas source (not illustrated). A processing liquid (e.g., chemical liquid or cleaning liquid) stored in the liquid source is supplied from the nozzle 21a toward the lower surface Wb of the substrate W via the at least one flow path. An inert gas (e.g., nitrogen) stored in the gas source is also supplied from the nozzle 21a toward the lower surface Wb of the substrate W via the at least one flow path.

Each of the plurality of shafts 22 is connected to the supply pipe 21 via a connector 22a. The plurality of shafts 22 extend in the vertical direction toward the support plate 12. The plurality of shafts 22 may be arranged at approximately equal intervals to form a circular shape as a whole when viewed from above. For example, when the number of shafts 22 is three, the plurality of shafts 22 may be arranged at intervals of approximately 120 degrees.

The drive 23 is connected to the supply pipe 21. The drive 23 is configured to operate based on an operation signal from the controller Ctr to raise or lower the supply pipe 21. The drive 23 may be a power source such as a linear actuator, for example. As the drive 23 raises or lowers the supply pipe 21, the supply pipe 21 and the plurality of shafts 22 connected to the supply pipe 21 move up and down between the lowered position (see FIG. 2) and the raised position (see FIG. 4).

As illustrated in FIG. 2, at the lowered position, the tip end portion (nozzle 21a) of the supply pipe 21 is located below the tips of the plurality of protrusions 12b. At the lowered position, tips of the plurality of shafts 22 are positioned below the uplifter 17. At the lowered position, since a restoring force of spring acts in a direction in which the spring 17c extends, the support plate 12 is pulled downward via the uplifting pin 17b. Thus, the convex 12a of the support plate 12 and the concave 11e of the rotary plate 11 fit each other, and the lower surface of the support plate 12 comes into contact with the upper surface of the rotary plate 11. Accordingly, the pressed portion 18a of the movable member 18 is pushed downward by the lower surface (conductor 12c) of the support plate 12 and is pressed and fit into the groove 11f formed in the rotary plate 11. Further, the upright portion 18b extends upright in the vertical direction, and the tip end portion 18c of the upright portion 18b comes into contact with the outer peripheral edge Wc of the substrate W supported by the plurality of protrusions 12b. As a result, the movable member 18 presses the outer peripheral edge Wc of the substrate W against the restrictor 14 to hold the substrate W together with the restrictor 14.

At the lowered position, the conductor 11d and the conductor 12c is in contact with each other, and the conductor 12c and the pressed portion 18a is in contact with each other. Therefore, the conductors 11d and 12c and the movable member 18 are electrically connected to the ground.

On the other hand, as illustrated in FIG. 4, when the supply pipe 21 rises from the lowered position to the raised position, the plurality of shafts 22 also rise together with the supply pipe 21 via the connector 22a. When the plurality of shafts 22 reach the uplifter 17, the uplifting pins 17b located at positions corresponding to the plurality of shafts 22 are pushed up by the respective shafts 22. Thus, the spring 17c is compressed, the support plate 12 is floated up from the rotary plate 11, and the plurality of protrusions 12b come into contact with the lower surface of the substrate W. At the same time, the pressurizing force of the spring 19 causes the upright portion 18b to collapse radially outward of the rotary plate 11. Therefore, holding the outer peripheral edge Wc of the substrate W by the restrictor 14 and the movable member 18 is released, and the substrate W is supported by the plurality of protrusions 12b. As the supply pipe 21 further rises to the raised position, the substrate W is floated up to a position above the cup 30. In this case, it is possible to deliver the substrate W to and from an external transport arm without interfering with other devices.

At the raised position, since the support plate 12 is floated up from the rotary plate 11, the conductor 11d and the conductor 12c are spaced apart from each other. Therefore, the conductor 12c and the movable member 18 are electrically disconnected from the ground.

The cup 30 functions as a liquid collection container for receiving the processing liquid that is supplied to an upper surface Wa and the lower surface Wb of the substrate W and shaken off from the substrate W. The cup 30 includes an inner cup 31, a middle cup 32, and an outer cup 33.

The inner cup 31 has an annular shape as a whole and is provided to surround the substrate W, which is held by the restrictor 14 and the movable member 18, from outside. The inner cup 31 is connected to the rotary plate 11 by a connector (not illustrated) such that a lower rim of the inner cup 31 is spaced apart from the upper surface of the rotary plate 11. Therefore, the inner cup 31 rotates along with the rotation of the rotary plate 11. Thus, the processing liquid supplied to the lower surface Wb of the substrate W and shaken off from the substrate W is discharged to the outer cup 33 from a gap between the lower rim of the inner cup 31 and the rotary plate 11.

The middle cup 32 has an annular shape as a whole and is provided to surround the inner cup 31 from outside. The middle cup 32 is connected to the rotary plate 11 by a connector (not illustrated) such that a lower rim of the middle cup 32 is spaced apart from the upper surface of the rotary plate 11. Therefore, the middle cup 32 rotates along with the rotation of the rotary plate 11. Thus, the processing liquid supplied onto the upper surface Wa of the substrate W and shaken off from the substrate W is discharged to the outer cup 33 from a gap between the lower rim of the middle cup 32 and the rotary plate 11.

The outer cup 33 has an annular shape as a whole, and extends from below the rotary plate 11 to a lateral side of the middle cup 32 to surround the rotary plate 11 and the middle cup 32 from outside. A liquid drain pipe 33a is provided in a bottom wall of the outer cup 33. The processing liquid discharged from the inner cup 31 and the middle cup 32 is received by the outer cup 33 and is discharged to the outside of the liquid processing unit U via the liquid drain pipe 33a.

The chemical liquid supplier 40 includes a liquid source 41, a pump 42, a valve 43, a pipe 44, a drive 45 (tube drive), and a supply tube 100A. The liquid source 41 is a supply source of the chemical liquid L1.

The chemical liquid L1 may include, for example, an alkaline or acidic chemical liquid (etching liquid) for removing a film on the upper surface Wa of the substrate W. The alkaline chemical liquid may include, for example, an SC-1 liquid (a mixed liquid of ammonia, hydrogen peroxide, and pure water). The acidic chemical liquid may include, for example, an SC-2 liquid (a mixed liquid of hydrochloric acid, hydrogen peroxide, and pure water), SPM (a mixed liquid of sulfuric acid and hydrogen peroxide), or HF/HNO₃ liquid (a mixed liquid of hydrofluoric acid and nitric acid). The film on the upper surface Wa of the substrate W may be a conductive film such as titanium nitride, tungsten, or cobalt.

The pump 42 is configured to operate based on an operation signal from the controller Ctr to send the chemical liquid L1 drawn from the liquid source 41 to the supply tube 100A via the pipe 44 and the valve 43. The valve 43 is configured to operate based on an operation signal from the controller Ctr to switch between an open state that allows fluid flow in the pipe 44 and a closed state that prevents fluid flow in the pipe 44. The pipe 44 connects the liquid source 41, the pump 42, the valve 43, and the supply tube 100A sequentially from an upstream side.

The drive 45 is connected to the supply tube 100A via an arm 46. The drive 45 is configured to operate based on an operation signal from the controller Ctr to drive the arm 46. Therefore, as the arm 46 moves, the supply tube 100A moves along the horizontal direction or vertical direction above the substrate W. The supply tube 100A may pivotably move, for example, between a discharge position where a discharge port of the supply tube 100A faces a central portion of the substrate W and a retracted position where the discharge port is retracted radially outward from the outer peripheral edge Wc of the substrate W.

The supply tube 100A is disposed above the substrate W such that the discharge port of the supply tube 100A faces the upper surface Wa of the substrate W. The supply tube 100A is configured to discharge the chemical liquid L1, which is sent from the pump 42, from the discharge port of the supply tube 100A toward the upper surface Wa of the substrate W. A detailed configuration of the supply tube 100A will be described later.

The cleaning liquid supplier 50 includes a liquid source 51, a pump 52, a valve 53, a pipe 54, a drive 55, and a supply tube 100B. The liquid source 51 is a supply source of the cleaning liquid L2.

The cleaning liquid L2 is, for example, a liquid for removing (rinsing off) the chemical liquid L1 supplied onto the upper surface Wa of the substrate W and film materials dissolved by the chemical liquid L1. The cleaning liquid L2 may include, for example, deionized water (DIW), ozone water, carbonated water (CO₂ water), and ammonia water.

The pump 52 is configured to operate based on an operation signal from the controller Ctr to send the cleaning liquid L2 drawn from the liquid source 51 to the supply tube 100B via the pipe 54 and the valve 53. The valve 53 is configured to operate based on an operation signal from the controller Ctr to switch between an open state that allows fluid flow in the pipe 54 and a closed state that prevents fluid flow in the pipe 54. The pipe 54 connects the liquid source 51, the pump 52, the valve 53, and the supply tube 100B sequentially from an upstream side.

The drive 55 is connected to the supply tube 100B via an arm 56. The drive 55 is configured to operate based on an operation signal from the controller Ctr to drive the arm 56. Therefore, as the arm 56 moves, the supply tube 100B moves along the horizontal direction or vertical direction above the substrate W. The supply tube 100B may pivotably move, for example, between a discharge position where a discharge port of the supply tube 100B faces the central portion of the substrate W and a retracted position where the discharge port is retracted radially outward from the outer peripheral edge Wc of the substrate W.

The supply tube 100B is disposed above the substrate W such that the discharge port of the supply tube 100B faces the upper surface Wa of the substrate W. The supply tube 100B is configured to discharge the cleaning liquid L2, which is sent from the pump 52, from the discharge port of the supply tube 100B toward the upper surface Wa of the substrate W. A detailed configuration of the supply tube 100B will be described later.

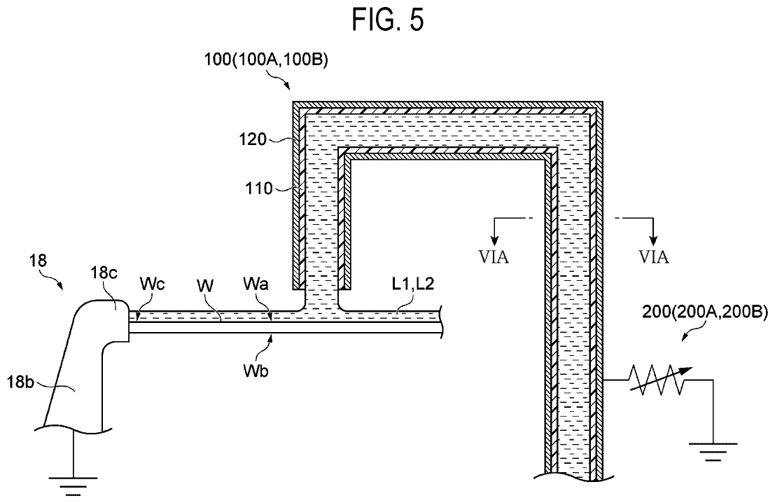

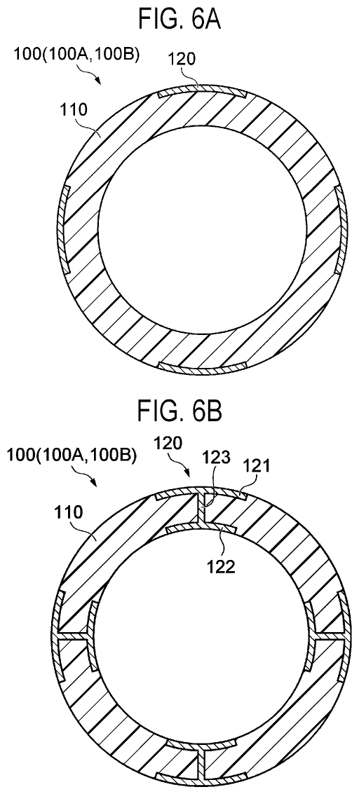

Here, the configuration of the supply tubes 100A and 100B will be described with reference to FIGS. 5 to 6B. In addition, in the present disclosure, the supply tubes 100A and 100B may be collectively referred to as the “supply tube 100.”

The supply tube 100 includes a tube main body 110 made of resin and a plurality of conductors 120 (first conductive member, second conductive member), as illustrated in FIGS. 5 and 6A. The tube main body 110 may be made of, for example, a thermoplastic fluororesin. The plurality of conductors 120 may be made of, for example, a thermoplastic fluororesin composition containing a conductive material.

In the example of FIGS. 5 and 6A, the plurality of conductors 120 are provided in an outer peripheral surface of the tube main body 110 and extend along an extension direction of the tube main body 110, while being spaced apart from one another in a radial direction of the tube main body 110. As illustrated in FIG. 6A, when the number of conductors 120 is four, the plurality of conductors 120 may be arranged at intervals of approximately 90 degrees in the radial direction of the tube main body 110.

As illustrated in FIG. 5, the plurality of conductors 120 are electrically connected to the ground via a variable resistor 200 having a variable resistance value. Specifically, one end of the variable resistor 200 is electrically connected to the plurality of conductors 120. The other end of the variable resistor 200 is electrically connected to the ground. Therefore, the other end of the variable resistor 200 is electrically connected to the movable member 18 which is in a grounded state. Details of the variable resistor 200 will be described later. In addition, in the present disclosure, the variable resistor 200 connected to the supply tube 100A may be referred to as a “variable resistor 200A,” and the variable resistor 200 connected to the supply tube 100B may be referred to as a “variable resistor 200B” (second variable resistor).

When the processing liquid (chemical liquid L1 or cleaning liquid L2) flows through the supply tube 100, an imaginary electrostatic capacitance is generated between the processing liquid and each of the plurality of conductors 120. Therefore, when the processing liquid is supplied from the supply tube 100 onto the upper surface of the substrate W held by the movable member 18 and comes into contact with the movable member 18 supporting the outer peripheral edge Wc of the substrate W, an electric circuit constituted by the movable member 18, the processing liquid, the supply tube 100, and the variable resistor 200 is formed.

In the electric circuit described above, when the resistance value of the variable resistor 200 is set to a relatively high value (first value), a current hardly flows between the supply tube 100 (the plurality of conductors 120) and the ground (the movable member 18). Therefore, static electricity in the processing liquid flowing through the supply tube 100 is hardly eliminated. Accordingly, when the processing liquid is supplied to the substrate W from the supply tube 100 and the substrate W is electrostatically charged, static electricity in the substrate W is eliminated by ions in the processing liquid. The first value at this time may be set to a value that electrically insulates the supply tube 100 (the plurality of conductors 120) and the ground (the movable member 18) from each other. The first value may be, for example, 100 kilo-ohms or more.

On the other hand, in the electric circuit described above, when the resistance value of the variable resistor 200 is set to a value (second value) lower than the first value, a current easily flows between the supply tube 100 (the plurality of conductors 120) and the ground (the movable member 18). Therefore, static electricity in the processing liquid flowing through the supply tube 100 is easily eliminated. Accordingly, when the processing liquid is supplied to the substrate W from the supply tube 100, the substrate W is suppressed from being electrostatically charged by the processing liquid. The second value at this time may be set to a value that establishes electrical conduction between the supply tube 100 (the plurality of conductors 120) and the ground (the movable member 18). The second value may be, for example, 1 kilo-ohms or less.

In addition, each of the plurality of conductors 120 may include an outer conductive body 121, an inner conductive body 122, and a connecting conductive body 123, as illustrated in FIG. 6B. A plurality of outer conductive bodies 121 are provided on the outer peripheral surface of the tube main body 110 and extend along the extension direction of the tube main body 110, while being spaced apart from one another in the radial direction of the tube main body 110.

As illustrated in FIG. 6B, when the number of outer conductive bodies 121 is four, the plurality of outer conductive bodies 121 may be arranged at intervals of approximately 90 degrees in the radial direction of the tube main body 110.

A plurality of inner conductive bodies 122 are provided on an inner peripheral surface of the tube main body 110 and extend along the extension direction of the tube main body 110, while being spaced apart from one another in the radial direction of the tube main body 110.

The inner conductive bodies 122 are positioned to face the outer conductive bodies 121, respectively. As illustrated in FIG. 6B, when the number of inner conductive bodies 122 is four, the plurality of inner conductive bodies 122 may be arranged at intervals of approximately 90 degrees in the radial direction of the tube main body 110.

A plurality of connecting conductive bodies 123 extend in a thickness direction of the tube main body 110 and integrally interconnect the outer conductive bodies 121 and the inner conductive bodies 122. Therefore, the outer conductive bodies 121, the inner conductive bodies 122, and the connecting conductive bodies 123 are electrically connected to one another.

### Controller

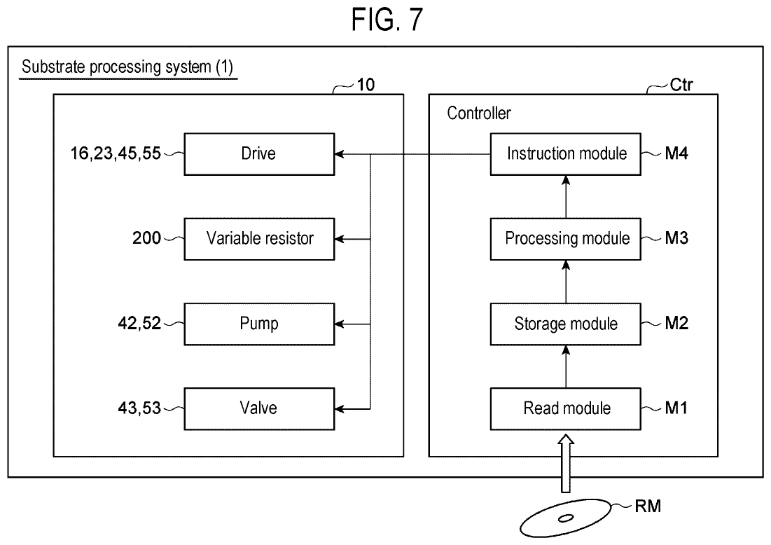

As illustrated in FIG. 7, the controller Ctr includes, as functional modules, a read module M1, a storage module M2, a processing module M3, and an instruction module M4. These functional modules are merely divisions of functions of the controller Ctr into a plurality of modules for convenience, and do not necessarily imply that hardware constituting the controller Ctr is physically divided into these modules. Each functional module is not limited to being implemented by executing a program, and may also be implemented by a dedicated electric circuit (e.g., a logic circuit) or an integrated circuit such as an application specific integrated circuit (ASIC).

The read module M1 is configured to read programs from a non-transitory computer-readable recording medium RM. The recording medium RM records programs for operating individual components (e.g., the drives 16, 23, 45, and 55, the variable resistor 200, the pumps 42 and 52, and the valves 43 and 53) of the substrate processing system 1. The recording medium RM may be, for example, a semiconductor memory, an optical recording disk, a magnetic recording disk, or a magneto-optical recording disk. The recording medium RM may be built into the substrate processing system 1, or may be provided separately from the substrate processing system 1.

The storage module M2 is configured to store various types of data. The storage module M2 may store, for example, programs read from the recording medium RM by the read module M1 and setting data input by an operator via an external input device (not illustrated).

The processing module M3 is configured to process various types of data. The processing module M3 may be configured to generate operation signals for operating individual components of the substrate processing system 1 based on, for example, various types of data stored in the storage module M2.

The instruction module M4 is configured to transmit the operation signals generated by the processing module M3 to individual components of the substrate processing system 1.

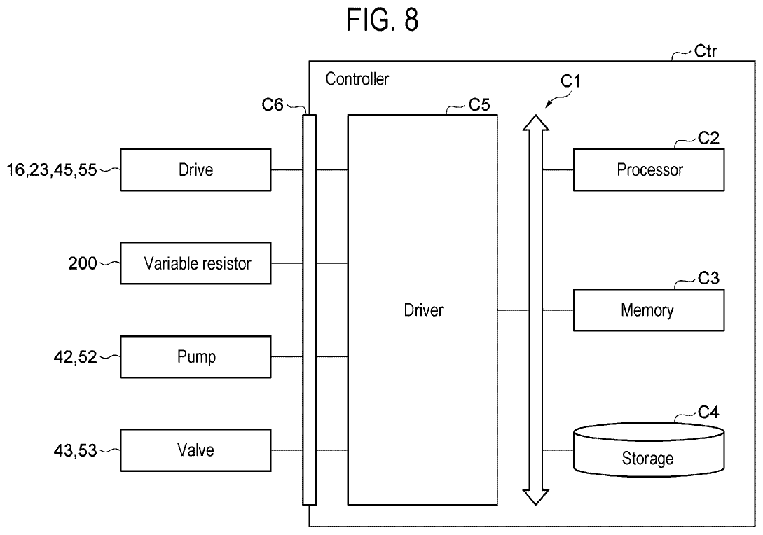

The hardware of the controller Ctr may be configured, for example, with a single or a plurality of computers for control. The controller Ctr may include, for example, a circuit C1 illustrated in FIG. 8 as a hardware configuration. The circuit C1 may be configured with electric circuit elements (circuitry). The circuit C1 may include, for example, a processor C2, a memory C3 (storage module), a storage C4 (storage module), a driver C5, and an input/output port C6. The processor C2 executes programs in cooperation with at least one of the memory C3 and the storage C4, and executes input and output of signals via the input/output port C6, thereby implementing each of the aforementioned functional modules. The memory C3 and the storage C4 function as the storage module M2. The driver C5 is a circuit that drives individual components of the substrate processing system 1. The input/output port C6 performs the input and output of signals between the driver C5 and individual components of the substrate processing system 1.

The substrate processing system 1 may include a single controller Ctr, or may include a controller group (controller) constituted by a plurality of controllers Ctr. In the latter case, each of the aforementioned functional modules may be implemented by a single controller Ctr, or may be implemented by a combination of two or more controllers Ctr. In a case where the controller Ctr is constituted by a plurality of computers (a plurality of circuits C1), each of the aforementioned functional modules may be implemented by a single computer (a single circuit C1), or may be implemented by a combination of two or more computers (two or more circuits C1). The controller Ctr may include a plurality of processors C2. In this case, each of the aforementioned functional modules may be implemented by a single processor C2, or may be implemented by a combination of two or more processors C2.

### Substrate Processing Method

Here, processing for the substrate W by the processing liquid will be described. First, the controller Ctr instructs the drive 23 to raise the supply pipe 21. Thus, the supply pipe 21 and the plurality of shafts 22 connected to the supply pipe 21 rise to the raised position (see FIG. 4). Next, the substrate W is placed on the plurality of protrusions 12b by a transport mechanism (not illustrated).

Subsequently, the controller Ctr instructs the drive 23 to lower the supply pipe 21. The supply pipe 21 and the plurality of shafts 22 connected to the supply pipe 21 are lowered to the lowered position (see FIG. 2). When the supply pipe 21 is lowered, the lower surface of the support plate 12 comes into contact with the upper surface of the rotary plate 11, and the pressed portion 18a of the movable member 18 is pushed downward by the lower surface (conductor 12c) of the support plate 12. Thus, the tip end portion 18c of the upright portion 18b comes into contact with the outer peripheral edge Wc of the substrate W supported on the plurality of protrusions 12b. As a result, the movable member 18 holds the substrate W together with the restrictor 14. Further, when the supply pipe 21 reaches the lowered position, the conductor 11d and the conductor 12c come into contact with each other, and the conductor 12c and the pressed portion 18a come into contact with each other. Therefore, the conductors 11d and 12c and the movable member 18 are electrically connected to the ground.

Subsequently, the controller Ctr instructs the drive 16 to rotate the rotary shaft 15. Thus, the substrate W placed on the plurality of protrusions 12b rotates, together with the rotary plate 11, the support plate 12, and the rotary shaft 15, in an approximately horizontal posture around the rotary shaft 15.

Subsequently, the controller Ctr instructs the drive 45 to move the supply tube 100A from the retracted position to the discharge position. At this time, the controller Ctr may instruct the variable resistor 200A to set the resistance value of the variable resistor 200A to the first value. A timing at which the resistance value of the variable resistor 200A is set to the first value may be simultaneous with a start of moving the supply tube 100A from the retracted position, or may be during the movement of the supply tube 100A from the retracted position to the discharge position.

Subsequently, the controller Ctr instructs the pump 42 and the valve 43 to supply the chemical liquid L1 of the liquid source 41 from the discharge port of the supply tube 100A onto the upper surface Wa of the substrate W. Thus, the chemical liquid L1 spreads over the entire upper surface Wa of the substrate W from the center toward the outer peripheral edge Wc of the substrate W, and comes into contact with the movable member 18. Therefore, the upper surface Wa of the substrate W is processed by the chemical liquid L1, and an electric circuit constituted by the movable member 18, the processing liquid, the supply tube 100A, and the variable resistor 200A is formed.

At this time, since the resistance value of the variable resistor 200A is set to the first value, a current hardly flows between the supply tube 100A (the plurality of conductors 120) and the ground (the movable member 18). Accordingly, when the chemical liquid L1 is supplied to the substrate W from the supply tube 100A and the substrate W is electrostatically charged, static electricity in the substrate W is eliminated by ions in the chemical liquid L1. In addition, a time duration for supplying the chemical liquid L1 onto the upper surface Wa of the substrate W while the resistance value of the variable resistor 200A is set to the first value may be appropriately determined according to a device formed on the upper surface Wa of the substrate W, and may be, for example, about five seconds.

Subsequently, while the chemical liquid L1 is continuously supplied onto the upper surface Wa of the substrate W, the controller Ctr instructs the variable resistor 200A to change the resistance value of the variable resistor 200A to the second value. Thus, a current easily flows between the supply tube 100A (the plurality of conductors 120) and the ground (the movable member 18). Therefore, static electricity in the chemical liquid L1 flowing through the supply tube 100A is easily eliminated. Accordingly, when the chemical liquid L1 is supplied to the substrate W from the supply tube 100A, the substrate W is suppressed from being electrostatically charged by the chemical liquid L1 is. In addition, a time duration for supplying the chemical liquid L1 onto the upper surface Wa of the substrate W while the resistance value of the variable resistor 200A is set to the second value may be appropriately determined according to a device formed on the upper surface Wa of the substrate W, and may be, for example, about twenty-five seconds.

Subsequently, the controller Ctr instructs the pump 42 and the valve 43 to stop the supply of the chemical liquid L1. The controller Ctr instructs the drive 45 to move the supply tube 100A from the discharge position to the retracted position.

Subsequently, the controller Ctr instructs the drive 55 to move the supply tube 100B from the retracted position to the discharge position. At this time, the controller Ctr may instruct the variable resistor 200B to set the resistance value of the variable resistor 200B to a value (third value) lower than the first value. A timing at which the resistance value of the variable resistor 200B is set to the third value may be simultaneous with a start of moving the supply tube 100B from the retracted position, or may be during the movement of the supply tube 100B from the retracted position to the discharge position.

Subsequently, the controller Ctr instructs the pump 52 and the valve 53 to supply the cleaning liquid L2 of the liquid source 51 from the discharge port of the supply tube 100B onto the upper surface Wa of the substrate W. Thus, the cleaning liquid L2 spreads over the entire upper surface Wa of the substrate W from the center toward the outer peripheral edge Wc of the substrate W, and comes into contact with the movable member 18. Therefore, the upper surface Wa of the substrate W is processed by the cleaning liquid L2, and an electric circuit constituted by the movable member 18, the processing liquid, the supply tube 100B, and the variable resistor 200B is formed.

At this time, since the resistance value of the variable resistor 200A is set to the third value, a current easily flows between the supply tube 100B (the plurality of conductors 120) and the ground (the movable member 18). Therefore, static electricity in the cleaning liquid L2 flowing through the supply tube 100B is easily eliminated. Accordingly, when the cleaning liquid L2 is supplied to the substrate W from the supply tube 100B, the substrate W is suppressed from being electrostatically charged by the cleaning liquid L2. The third value at this time may be set to a value that establishes electrical conduction between the supply tube 100B (the plurality of conductors 120) and the ground (the movable member 18). The third value may be the same as the second value, and may be, for example, 1 kilo-ohms or less. In addition, a time duration for supplying the cleaning liquid L2 onto the upper surface Wa of the substrate W while the resistance value of the variable resistor 200B is set to the third value may be appropriately determined according to a device formed on the upper surface Wa of the substrate W, and may be, for example, about thirty seconds.

Subsequently, the controller Ctr instructs the pump 52 and the valve 53 to stop the supply of the cleaning liquid L2. The controller Ctr instructs the drive 55 to move the supply tube 100B from the discharge position to the retracted position.

Subsequently, the substrate W is continuously rotated for a predetermined time. Thus, the cleaning liquid L2 that has adhered to the substrate W is shaken off by the rotation of the substrate W, and the surface of the substrate W is dried. The predetermined time may be appropriately determined according to a processing status of the substrate W, and may be, for example, about forty seconds.

Subsequently, the controller Ctr instructs the drive 23 to raise the supply pipe 21. Thus, the supply pipe 21 and the plurality of shafts 22 connected to the supply pipe 21 rise to the raised position (see FIG. 4). Subsequently, the substrate W supported on the plurality of protrusions 12b is unloaded from the liquid processing unit U by a transport mechanism (not illustrated).

By the processes described above, processing the substrate W is completed.

### Operations

According to the above example, first, the chemical liquid L1 is supplied onto the upper surface Wa of the substrate W via the supply tube 100A while the resistance value of the variable resistor 200A is set to the relatively high first value. Thus, even when the substrate Wis electrostatically charged, a current hardly flows between the plurality of conductors 120 and the movable member 18 via the variable resistor 200A. Therefore, since electric charges in the chemical liquid L1 gradually neutralize electric charges on the substrate W, it is possible to suppress generation of arcing during the substrate processing process.

According to the above example, the resistance value of the variable resistor 200A is changed to the relatively low second value while the chemical liquid L1 is continuously supplied. Thus, a current easily flows between the plurality of conductors 120 and the movable member 18 via the variable resistor 200A. Therefore, since electric charges in the chemical liquid L1 flowing through the supply tube 100A are neutralized, it is possible to suppress the substrate W from being electrostatically charged by the electric charges in the chemical liquid L1 while suppressing generation of static electricity in the supply tube 100A.

According to the above example, it is possible to effectively suppress generation of arcing at an initial stage of discharging the chemical liquid L1 onto the substrate W, generation of static electricity in the supply tube 100A by continuously discharging the chemical liquid L1 onto the substrate W, and the electrostatic charging of the substrate W by continuously discharging the chemical liquid L1 onto the substrate W.

According to the above example, the cleaning liquid L2 is supplied onto the upper surface Wa of the substrate W via the supply tube 100B while the resistance value of the variable resistor 200B is set to the relatively low third value. Thus, a current easily flows between the plurality of conductors 120 and the movable member 18 via the variable resistor 200B.

Therefore, it is possible to suppress the substrate W from being electrostatically charged by friction between the cleaning liquid L2 and the substrate W as the cleaning liquid L2 flows over the upper surface Wa of the substrate W.

According to the above example, the chemical liquid L1 may be supplied onto the upper surface Wa of the substrate W via the supply tube 100A in a state in which the plurality of conductors 120 and the movable member 18 are electrically insulated from each other via the variable resistor 200A. Thus, even when the substrate W is electrostatically charged, no current flows between the plurality of conductors 120 and the movable member 18 via the variable resistor 200A. Therefore, it is possible to suppress generation of arcing during the procedure of substrate processing more effectively. Further, according to the above example, the chemical liquid L1 is supplied onto the upper surface Wa of the substrate W via the supply tube 100A in a state in which the plurality of conductors 120 and the movable member 18 are electrically conducted to each other via the variable resistor 200A. Thus, a current flows between the plurality of conductors 120 and the movable member 18 via the variable resistor 200A. Therefore, it is possible to suppress the substrate W from being electrostatically charged by the electric charges in the chemical liquid L1 more effectively, while suppressing generation of static electricity in the supply tube 100A.

According to the above example, the resistance value of the variable resistor 200A may be set to the first value while the supply tube 100A is being moved to locate the discharge port of the supply tube 100A over the upper surface Wa of the substrate W. In this case, the resistance value of the variable resistor 200A is set to the relatively high first value before the chemical liquid L1 is discharged onto the upper surface Wa of the substrate W. Thus, a current hardly flows between the plurality of conductors 120 and the movable member 18 via the variable resistor 200A before the chemical liquid L1 is discharged onto the upper surface Wa of the substrate W. Therefore, it is possible to suppress generation of arcing during the procedure of substrate processing more reliably.

### EXAMPLES OF VARIABLE RESISTOR

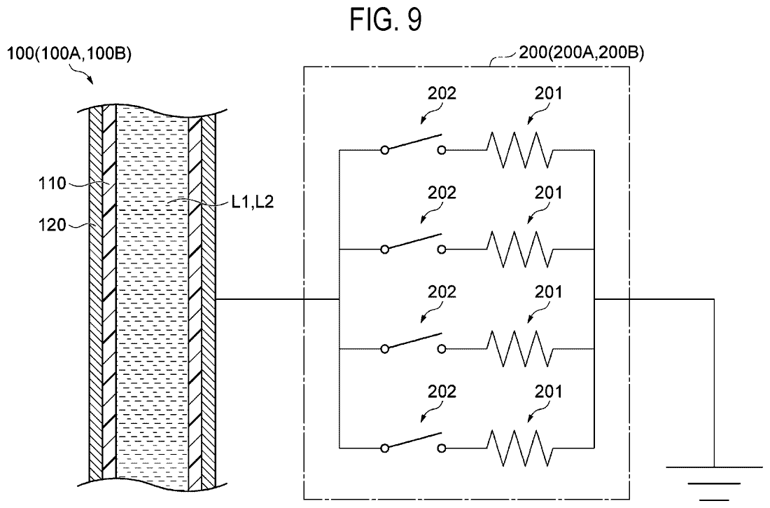

Here, examples of the variable resistor 200 will be described with reference to FIGS. 9 to 12B.

### First Example

FIG. 9 illustrates the variable resistor 200 according to a first example. The variable resistor 200 according to the first example may be a potentiometer. Specifically, the variable resistor 200 may be constituted by a plurality of resistors 201 connected in parallel and a plurality of switches 202 respectively connected in series to the resistors 201. With this configuration, a combined resistance value of the variable resistor 200 varies according to the numbers of opened and closed switches 202.

A resistance value of each resistor 201 may be set such that the combined resistance value of the variable resistor 200 varies between the first value and the second value. The resistance values of the plurality of resistors 201 may be set such that all the resistance values are the same, such that at least one resistance value is different from other resistance values, or such that all the resistance values are different from one another. A highest resistance value among the plurality of resistors 201 may be 100 kilo-ohms or more. A lowest resistance value among the plurality of resistors 201 may be one kilo-ohm or less.

According to the first example, it is possible to change the resistance value of the variable resistor 200 with a simple configuration.

### Second Example

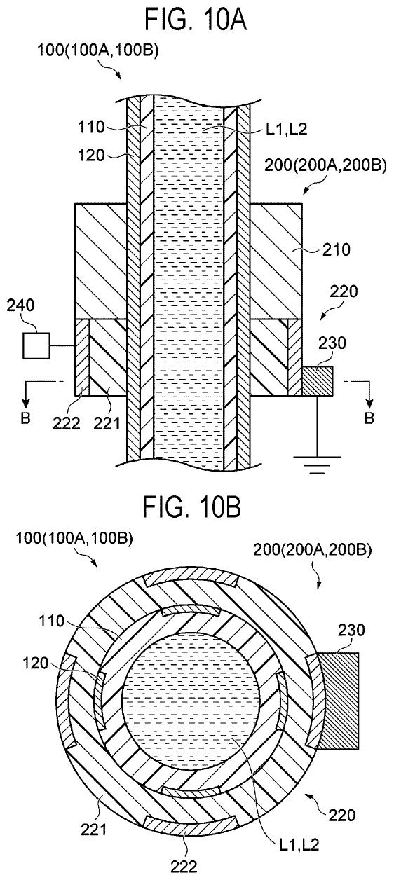

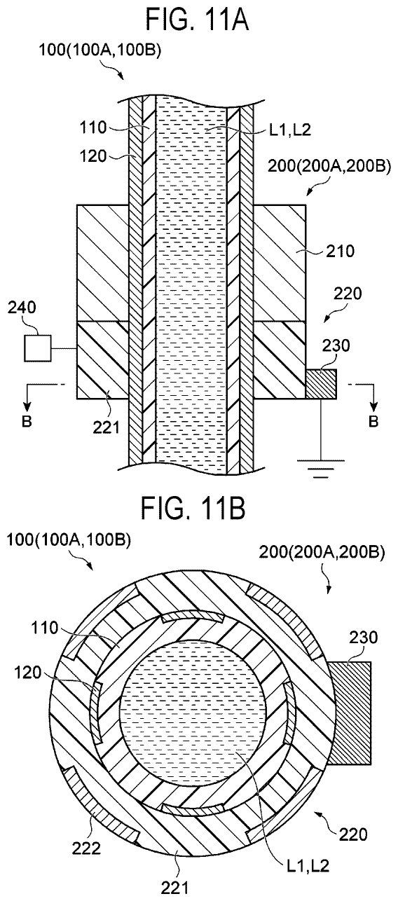

FIGS. 10A to 11B illustrate the variable resistor 200 according to a second example. The variable resistor 200 according to the second example includes a conductive ring 210, a rotator 220, a conductor 230, and a drive 240.

The conductive ring 210 is a cylindrical member made of a conductive material. The conductive ring 210 is attached to an outer peripheral surface of the supply tube 100. Thus, the conductive ring 210 is electrically connected to the plurality of conductors 120 of the supply tube 100.

The rotator 220 includes an insulator 221 and a plurality of conductors 222. The insulator 221 is a cylindrical member made of a resin material. In the example of FIGS. 10A to 11B, the plurality of conductors 222 are provided on an outer peripheral surface of the insulator 221 and extend along an extension direction of the insulator 221, while being spaced apart from one another in a radial direction of the insulator 221. As illustrated in FIGS. 10B and 11B, when the number of conductors 222 is four, the plurality of conductors 222 may be arranged at intervals of approximately 90 degrees in the radial direction of the insulator 221.

The rotator 220 is provided rotatably with respect to the outer peripheral surface of the supply tube 100 and in contact with the conductive ring 210. Therefore, the conductive ring 210 and the plurality of conductors 222 are electrically connected to each other. In the example of FIGS. 10A to 11B, an upper end surface of the rotator 220 is in contact with a lower end surface of the conductive ring 210. However, a lower end surface of the rotator 220 may be in contact with an upper end surface of the conductive ring 210.

The conductor 230 is made of a conductive material and is arranged to be in contact with the outer peripheral surface of the rotator 220. The conductor 230 is electrically connected to the ground.

The drive 240 is configured to operate based on an operation signal from the controller Ctr to rotate the rotator 220. When the drive 240 rotates the rotator 220, the rotator 220 rotates between a connection position (see FIGS. 10A and 10B) where one of the plurality of conductors 222 is electrically connected to the conductive member 230, and a non-connection position (see FIGS. 11A and 11B) where none of the plurality of conductors 222 is electrically connected to the conductive member 230. The drive 240 may be, for example, a rotary motor.

According to the second example, the controller Ctr may instruct the drive 240 to drive the rotator 220 such that the chemical liquid L1 is supplied onto the upper surface Wa of the substrate W via the supply tube 100A in a state in which the plurality of conductors 120 and the movable member 18 are electrically insulated from each other via the variable resistor 200A (see FIGS. 11A and 11B). Thereafter, while continuously supplying the chemical liquid LI to the substrate W, the controller Ctr may instruct the drive 240 to drive the rotator 220 such that the plurality of conductors 120 and the movable member 18 are electrically conducted to each other via the variable resistor 200A (see FIGS. 10A and 10B). In this case, the plurality of conductors 120 and the movable member 18 can be switched between an electrically insulated state and an electrically conducted state via the variable resistor 200A with a simple configuration of rotating the rotator 220.

### Third Example

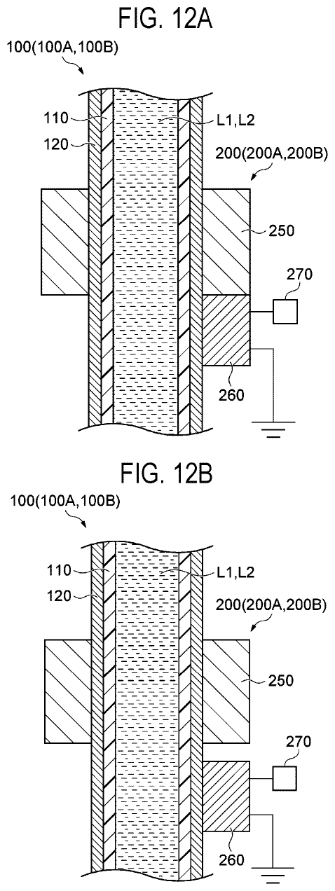

FIGS. 12A and 12B illustrate the variable resistor 200 according to a third example. The variable resistor 200 according to the third example includes a conductive ring 250, a conductor 260, and a drive 270.

The conductive ring 250 has the same configuration as the conductive ring 210 of the variable resistor 200 according to the second example, and thus, a description thereof will be omitted.

The conductor 260 is made of a conductive material and is configured to be movable up and down. The conductor 260 is electrically connected to the ground.

The drive 270 is configured to operate based on an operation signal from the controller Ctr to move the conductor 260 up and down. The drive 270 moves the conductor 260 up and down, such that the conductor 260 moves between a connection position where the conductive ring 250 and the conductor 260 are electrically connected to each other (see FIG. 12A), and a non-connection position where the conductive ring 250 and the conductor 260 are not electrically connected to each other (see FIG. 12B). The drive 270 may be, for example, a rotary motor.

According to the third example, the controller Ctr may instruct the drive 270 to drive the conductor 260 such that the chemical liquid L1 is supplied onto the upper surface Wa of the substrate W via the supply tube 100A in a state in which the plurality of conductors 120 and the movable member 18 are electrically insulated from each other via the variable resistor 200A (see FIG. 12B). Thereafter, while continuously supplying the chemical liquid LI to the substrate W, the controller Ctr may instruct the drive 270 to drive the conductor 260 such that the plurality of conductors 120 and the movable member 18 are electrically conducted to each other via the variable resistor 200A (see FIG. 12A). In this case, the plurality of conductors 120 and the movable member 18 can be switched between an electrically insulated state and an electrically conducted state via the variable resistor 200A, with a simple configuration of moving the conductor 260.

### MODIFICATIONS

The disclosure in this specification should be regarded as illustrative and not restrictive in all respects. Various omissions, substitutions, changes, and others may be made to the above examples without departing from the scope and spirit of the claims.
(1) The resistance value of the variable resistor 200 may change discretely or continuously. That is, when the resistance value of the variable resistor 200 transitions from the first value to the second value, the resistance value may change immediately from the first value to the second value, or may change gradually from the first value to the second value. The same applies to when the resistance value of the variable resistor 200 transitions from the second value to the third value.
(2) In the above example, switching between holding and not holding the substrate W is performed by moving the movable member 18 by using the rotary shaft 18d. However, switching between holding and not holding the substrate W is not limited to this configuration. For example, switching between holding and not holding the substrate W may be performed by moving the movable member 18 in the radial direction of the substrate W.

### OTHER EXAMPLES

### Example 1

An example of a substrate processing method includes a holding process of holding an outer peripheral edge of a substrate by a conductive holder, and after the holding process, a chemical liquid supply process of supplying a chemical liquid onto an upper surface of the substrate via a first supply tube having a first conductive member provided on an outer peripheral surface of the first supply tube. The first conductive member is electrically connected to one end of a first variable resistor having a variable resistance value. The holder is electrically connected to the other end of the first variable resistor. The chemical liquid supply process includes: a first sub-process of setting the resistance value of the variable resistor to a first value; after the first sub-process, a second sub-process of supplying the chemical liquid onto the upper surface of the substrate via the first supply tube; and after the second sub-process, a third sub-process of changing the resistance value of the variable resistor to a second value lower than the first value, while continuously supplying the chemical liquid from the second sub-process onto the upper surface of the substrate via the first supply tube.

The substrate may be electrostatically charged during a pre-processing for the substrate (e.g., etching). Therefore, when the holder and the conductive member of the supply tube are electrically connected to their respective grounds, for example, and a chemical liquid having polarity is supplied to the electrostatically charged substrate, the chemical liquid acts as a conductive wire and the electric charges on the substrate to move from one ground to the other ground. This causes a current to flow across the substrate and electrical discharge from the substrate known as arcing (surface discharge) to be generated. Thus, a device (e.g., a pattern) formed on the upper surface of the substrate may be damaged due to dielectric breakdown.

Further, in a case where the supply tube having the conductive member provided on the outer peripheral surface of the supply tube is not used, it is concerned that static electricity may be generated by a flow of a chemical liquid without having polarity, alcohol, or the like through the tube, and may act as an ignition source. In addition, the substrate may be electrostatically charged by the chemical liquid without having polarity, alcohol, or the like being discharged onto and flowing over the upper surface of the substrate.

However, according to Example 1, in the second sub-process of the chemical liquid process, the chemical liquid is first supplied onto the upper surface of the substrate via the first supply tube while the resistance value of the first variable resistor is set to the relatively high first value. Thus, even when the substrate is electrostatically charged, a current hardly flows between the first conductive member and the holder via the first variable resistor. Therefore, since the electric charges in the chemical liquid gradually neutralize the electric charges on the substrate, it is possible to suppress generation of arcing during the procedure of substrate processing.

In addition, according to Example 1, in the third sub-process following the second sub-process, the resistance value of the first variable resistor is changed to the relatively low second value while continuously supplying the chemical liquid from the second sub-process onto the upper surface of the substrate via the first supply tube. Thus, a current easily flows between the first conductive member and the holder via the first variable resistor. Therefore, since the electric charges in the chemical liquid flowing through the first supply tube are neutralized, it is possible to suppress the substrate from being electrostatically charged by the electric charges in the chemical liquid while suppressing generation of static electricity in the supply tube.

From the above, according to Example 1, it is possible to effectively suppress generation of arcing at an initial stage of discharging the chemical liquid onto the substrate, generation of static electricity in the supply tube due to the continuous discharge of the chemical liquid onto the substrate, and electrostatic charging of the substrate due to the continuous discharge of the chemical liquid onto the substrate.

### Example 2

The substrate processing method of Example 1 may further include, after the chemical liquid supply process, a cleaning liquid supply process of supplying a cleaning liquid onto the upper surface of the substrate via a second supply tube having a second conductive member provided on an outer peripheral surface of the second supply tube. The second conductive member may be electrically connected to one end of a second variable resistor having a variable resistance value, the holder may be electrically connected to the other end of the second variable resistor, and the cleaning liquid supply process may include supplying the cleaning liquid onto the upper surface of the substrate via the second supply tube while the resistance value of the second variable resistor is set to a third value lower than the first value. In this case, the cleaning liquid is supplied onto the upper surface of the substrate via the second supply tube while the resistance value of the second variable resistor is set to the relatively low third value. Thus, a current easily flows between the second conductive member and the holder via the second variable resistor. Therefore, it is possible to suppress the substrate from being electrostatically charged by friction between the cleaning liquid and the substrate as the cleaning liquid flows over the upper surface of the substrate.

### Example 3

In the substrate processing method of Example 1 or 2, the first sub-process may include setting the resistance value of the first variable resistor such that the first conductive member and the holder are electrically insulated from each other via the first variable resistor, and the third sub-process may include setting the resistance value of the first variable resistor such that the first conductive member and the holder are electrically conducted to each other via the first variable resistor. In this case, in the second sub-process, the chemical liquid is supplied onto the upper surface of the substrate via the first supply tube while the first conductive member and the holder are electrically insulated from each other via the first variable resistor. Thus, even when the substrate is electrostatically charged, a current hardly flows between the first conductive member and the holder via the first variable resistor. Therefore, it is possible to suppress generation of arcing during the procedure of substrate processing more effectively. Further, in this case, in the third sub-process, the chemical liquid is supplied onto the upper surface of the substrate via the first supply tube while the first conductive member and the holder are electrically conducted to each other via the first variable resistor. Thus, a current flows between the first conductive member and the holder via the first variable resistor. Therefore, it is possible to suppress the substrate from being electrostatically charged by the electric charges in the chemical liquid more effectively, while suppressing generation of static electricity in the first supply tube.

### Example 4

In the substrate processing method of any one of Examples 1 to 3, the first sub-process may include setting the resistance value of the first variable resistor to the first value while moving the first supply tube so that a discharge port of the first supply tube is positioned above the upper surface of the substrate. In this case, the resistance value of the first variable resistor is set to the relatively high first value before the chemical liquid is discharged onto the upper surface of the substrate. Thus, a current hardly flows between the first conductive member and the holder via the first variable resistor before the chemical liquid is discharged onto the upper surface of the substrate. Therefore, it is possible to suppress generation of arcing during the procedure of substrate processing more reliably.

### Example 5

An example of a substrate processing apparatus includes: a conductive holder configured to hold an outer peripheral edge of a substrate; a chemical liquid supplier configured to supply a chemical liquid onto an upper surface of the substrate via a first supply tube having a first conductive member provided on an outer peripheral surface of the first supply tube; a first variable resistor having one end electrically connected to the first conductive member and the other end electrically connected to the holder, and configured to have a variable resistance value; and a controller. The controller is configured to execute: a first process of controlling the holder to hold the outer peripheral edge of the substrate; after the first process, a second process of controlling the first variable resistor to set the resistance value of the first variable resistor to a first value; after the second process, a third process of controlling the chemical liquid supplier to supply the chemical liquid onto the upper surface of the substrate via the first supply tube; and after the third process, a fourth process of controlling the chemical liquid supplier and the first variable resistor to change the resistance value of the first variable resistor to a second value lower than the first value, while continuously supplying the chemical liquid from the third process. In this case, the same effects as those of the method in Example 1 are obtained.

### Example 6

The substrate processing apparatus of Example 5 may further include: a cleaning liquid supplier configured to supply a cleaning liquid onto the upper surface of the substrate via a second supply tube having a second conductive member provided on an outer peripheral surface of the second supply tube; and a second variable resistor having one end electrically connected to the second conductive member and the other end electrically connected to the holder, and configured to have a variable resistance value. The controller may be further configured to execute, after the fourth process, a fifth process of controlling the cleaning liquid supplier and the second variable resistor to supply the cleaning liquid onto the upper surface of the substrate via the second supply tube while the resistance value of the second variable resistor is set to a third value lower than the first value. In this case, the same effects as those of the method in Example 2 are obtained.

### Example 7

In the substrate processing apparatus of Example 5 or 6, the second process may further include setting the resistance value of the first variable resistor such that the first conductive member and the holder are electrically insulated from each other via the first variable resistor, and the fourth process may further include setting the resistance value of the first variable resistor such that the first conductive member and the holder are electrically conducted to each other via the first variable resistor. In this case, the same effects as those of the method in Example 3 are obtained.

### Example 8

The substrate processing apparatus of any one of Examples 5 to 7 may further include a tube drive configured to move the first supply tube above the upper surface of the substrate, and the second process may further include operating the first variable resistor so that the resistance value of the first variable resistor is set to the first value, while the tube drive moves the first supply tube so that a discharge port of the first supply tube is positioned above the upper surface of the substrate. In this case, the same effects as those of the method in Example 4 are obtained.

### Example 9

In the substrate processing apparatus of any one of Examples 5 to 8, the first variable resistor may be a potentiometer. In this case, it is possible to change the resistance value of the first variable resistor with a simple configuration.

### Example 10

In the substrate processing apparatus of any one of Examples 5 to 8, the first variable resistor may include: a rotator having an insulator and a conductor, and provided rotatable with respect to the outer peripheral surface of the first supply tube; and a drive configured to rotationally drive the rotator. The second process may further include supplying the chemical liquid onto the upper surface of the substrate via the first supply tube while the first conductive member and the holder are electrically insulated from each other via the first variable resistor by driving the rotator by the drive so that the insulator is disposed between the first conductive member and the holder. The third process may further include supplying the chemical liquid onto the upper surface of the substrate via the first supply tube while the first conductive member and the holder are electrically conducted to each other via the first variable resistor by driving the rotator by the drive so that the conductor is disposed between the first conductive member and the holder. In this case, the first conductive member and the holder can be switched between an electrical insulated stated and an electrically conducted state via the first variable resistor, with a simple configuration of rotating the rotator.

### Example 11

In the substrate processing apparatus of any one of Examples 5 to 8, the first variable resistor may include a conductor, and a drive configured to drive the conductor so that the conductor moves toward and away from the first conductive member. The second process may further include supplying the chemical liquid onto the upper surface of the substrate via the first supply tube while the first conductive member and the holder are electrically insulated from each other via the first variable resistor, by driving the conductor by the drive so that the conductor is spaced apart from the first conductive member. The third process may further include supplying the chemical liquid onto the upper surface of the substrate via the first supply tube while the first conductive member and the holder are electrically conducted to each other via the first variable resistor, by driving the conductor by the drive so that the conductor is brought into contact with the first conductive member. In this case, the first conductive member and the holder can be switched between an electrical insulated stated and an electrically conducted state via the first variable resistor, with a simple configuration of moving the conductor.

According to a substrate processing method and substrate processing apparatus of the present disclosure, it is possible to suppress generation of arcing during a procedure of substrate processing.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

1. A substrate processing method comprising:
a holding process of holding an outer peripheral edge of a substrate by a conductive holder; and
after the holding process, a chemical liquid supply process of supplying a chemical liquid onto an upper surface of the substrate via a first supply tube having a first conductive member provided on an outer peripheral surface of the first supply tube, wherein the first conductive member is electrically connected to one end of a first variable resistor having a variable resistance value,
wherein the holder is electrically connected to the other end of the first variable resistor, and
wherein the chemical liquid supply process includes:
a first sub-process of setting the resistance value of the first variable resistor to a first value;
after the first sub-process, a second sub-process of supplying the chemical liquid onto the upper surface of the substrate via the first supply tube; and
after the second sub-process, a third sub-process of changing the resistance value of the first variable resistor to a second value lower than the first value, while continuously supplying the chemical liquid from the second sub-process onto the upper surface of the substrate via the first supply tube.

2. The substrate processing method of claim 1, further comprising, after the chemical liquid supply process, a cleaning liquid supply process of supplying a cleaning liquid onto the upper surface of the substrate via a second supply tube having a second conductive member provided on an outer peripheral surface of the second supply tube,
wherein the second conductive member is electrically connected to one end of a second variable resistor having a variable resistance value,
wherein the holder is electrically connected to the other end of the second variable resistor, and
wherein the cleaning liquid supply process includes supplying the cleaning liquid onto the upper surface of the substrate via the second supply tube while the resistance value of the second variable resistor is set to a third value lower than the first value.

3. The substrate processing method of claim 2, wherein the first sub-process includes setting the resistance value of the first variable resistor such that the first conductive member and the holder are electrically insulated from each other via the first variable resistor, and
wherein the third sub-process includes setting the resistance value of the first variable resistor such that the first conductive member and the holder are electrically conducted to each other via the first variable resistor.

4. The substrate processing method of claim 1, wherein the first sub-process includes setting the resistance value of the first variable resistor such that the first conductive member and the holder are electrically insulated from each other via the first variable resistor, and
wherein the third sub-process includes setting the resistance value of the first variable resistor such that the first conductive member and the holder are electrically conducted to each other via the first variable resistor.

5. The substrate processing method of claim 1, wherein the first sub-process includes setting the resistance value of the first variable resistor to the first value while moving the first supply tube so that a discharge port of the first supply tube is positioned above the upper surface of the substrate.

6. A substrate processing apparatus comprising:
a conductive holder configured to hold an outer peripheral edge of a substrate;
a chemical liquid supplier configured to supply a chemical liquid onto an upper surface of the substrate via a first supply tube having a first conductive member provided on an outer peripheral surface of the first supply tube;
a first variable resistor having one end electrically connected to the first conductive member and the other end electrically connected to the holder, and configured to have a variable resistance value; and
a controller,
wherein the controller is configured to execute:
a first process of controlling the holder to hold the outer peripheral edge of the substrate;
after the first process, a second process of controlling the first variable resistor to set the resistance value of the first variable resistor to a first value;
after the second process, a third process of controlling the chemical liquid supplier to supply the chemical liquid onto the upper surface of the substrate via the first supply tube; and
after the third process, a fourth process of controlling the chemical liquid supplier and the first variable resistor to change the resistance value of the first variable resistor to a second value lower than the first value, while continuously supplying the chemical liquid from the third process.

7. The substrate processing apparatus of claim 6, further comprising:
a cleaning liquid supplier configured to supply a cleaning liquid onto the upper surface of the substrate via a second supply tube having a second conductive member provided on an outer peripheral surface of the second supply tube; and
a second variable resistor having one end electrically connected to the second conductive member and the other end electrically connected to the holder, and configured to have a variable resistance value,
wherein the controller is further configured to execute, after the fourth process a fifth process of controlling the cleaning liquid supplier and the second variable resistor to supply the cleaning liquid onto the upper surface of the substrate via the second supply tube while the resistance value of the second variable resistor is set to a third value lower than the first value.

8. The substrate processing apparatus of claim 7, wherein the second process further includes setting the resistance value of the first variable resistor such that the first conductive member and the holder are electrically insulated from each other via the first variable resistor, and
wherein the fourth process further includes setting the resistance value of the first variable resistor such that the first conductive member and the holder are electrically conducted to each other via the first variable resistor.

9. The substrate processing apparatus of claim 6, wherein the second process further includes setting the resistance value of the first variable resistor such that the first conductive member and the holder are electrically insulated from each other via the first variable resistor, and
wherein the fourth process further includes setting the resistance value of the first variable resistor such that the first conductive member and the holder are electrically conducted to each other via the first variable resistor.

10. The substrate processing apparatus of claim 6, further comprising a tube drive configured to move the first supply tube above the upper surface of the substrate,
wherein the second process further includes operating the first variable resistor so that the resistance value of the first variable resistor becomes the first value, while the tube drive moves the first supply tube so that a discharge port of the first supply tube is positioned above the upper surface of the substrate.

11. The substrate processing apparatus of claim 6, wherein the first variable resistor is a potentiometer.

12. The substrate processing apparatus of claim 6, wherein the first variable resistor includes:
a rotator having an insulator and a conductor, and provided to be rotatable with respect to the outer peripheral surface of the first supply tube; and
a drive configured to rotationally drive the rotator,
wherein the second process further includes supplying the chemical liquid onto the upper surface of the substrate via the first supply tube while the first conductive member and the holder are electrically insulated from each other via the first variable resistor, by driving the rotator by the drive so that the insulator is disposed between the first conductive member and the holder, and
wherein the third process further includes supplying the chemical liquid onto the upper surface of the substrate via the first supply tube while the first conductive member and the holder are electrically conducted to each other via the first variable resistor, by driving the rotator by the drive so that the first conductor is disposed between the first conductive member and the holder.

13. The substrate processing apparatus of claim 6, wherein the first variable resistor includes:
a conductor; and
a drive configured to drive the conductor so that the conductor moves toward and away from the first conductive member,
wherein the second process further includes supplying the chemical liquid onto the upper surface of the substrate via the first supply tube while the first conductive member and the holder are electrically insulated from each other via the first variable resistor, by driving the conductor by the drive so that the conductor is spaced apart from the first conductive member, and
wherein the third process further includes supplying the chemical liquid onto the upper surface of the substrate via the first supply tube while the first conductive member and the holder are electrically conducted to each other via the first variable resistor, by driving the conductor by the drive so that the conductor is brought into contact with the first conductive member.
